(19) United States
(12) Patent Application Publication
(10) Pub. No.: US 2026/0123258 A1
(43) Pub. Date: Apr. 30, 2026

(54) DISPLAY PANEL AND DISPLAY APPARATUS

(71) Applicant: Hubei Yangtze Industrial Innovation Center Of Advanced Display Co., Ltd., Wuhan (CN)

(72) Inventor: Leilei CAO, Wuhan (CN)

(21) Appl. No.: 19/432,948

(22) Filed: Dec. 25, 2025

(30) Foreign Application Priority Data
Dec. 27, 2024 (CN) 202411960350.2

(51) Int. Cl. H10K 59/80; H10K 59/122

(52) U.S. Cl. CPC H10K 59/8792; H10K 59/122

(57) ABSTRACT

The present disclosure provides a display panel and a display apparatus. The display panel includes a display substrate, a pixel definition layer, a plurality of sub-pixels and a support layer. The pixel definition layer includes a plurality of pixel definition portions, and an opening area is provided between two adjacent pixel definition portions. The sub-pixel includes a light-emitting layer, and the light-emitting layer is at least partially located in the opening area. The support layer is located on a side of the light-emitting layer away from the display substrate, and includes a plurality of support portions. The support portion is located on a side of the pixel definition portion away from the display substrate, and include a first support portion. Along a first direction, a minimum distance between the first support portion and the first opening area is D1, a minimum distance between the first support portion and the second opening area is D2, and D1≠D2. The first direction is perpendicular to a thickness direction of the display substrate. The display panel can improve the differentiated anti-peeping effect of the display panel.

### CROSS-REFERENCE TO RELATED APPLICATION

The present application claims priority to Chinese Patent Application No. 202411960350.2, filed on December 27, 2024, the content of which is incorporated herein by reference in its entirety.

### TECHNICAL FIELD

The present disclosure relates to the technical field of displaying and, in particular, to a display panel and a display apparatus.

### BACKGROUND

With the development of display technology, vehicle display are have a trend of intelligence and large screens. As the display brightness of the display panel increases, the reflected light from the front windshield is enhanced and the projection is intensified, which interferes with the driver's vision, especially seriously affecting driving safety during night driving. To eliminate the projection of reflected light from the front windshield, there is a serious loss of brightness, and the differentiated anti-peeping effect in different directions is poor.

Therefore, there is an urgent need for a display panel that can solve the technical problem of poor differentiated anti-peeping effect of the display panel in the prior art.

### SUMMARY

The main purpose of the present disclosure is to provide a display panel and a display apparatus

To achieve the above purpose, an aspect of the present disclosure provides a display panel, including: a display substrate; a pixel definition layer; a plurality of sub-pixels; and a support layer. The pixel definition layer is provided at a side of the display substrate. The pixel definition layer includes a plurality of pixel definition portions, and an opening area is provided between two adjacent pixel definition portions. At least one of the sub-pixels includes a light-emitting layer, and the light-emitting layer is at least partially located in the opening area. The support layer is located at a side of the light-emitting layer away from the display substrate. The support layer includes a plurality of support portions. The support portions are located on a side of the pixel definition portions away from the display substrate. The support portions include a first support portion. Along a first direction, the opening area includes a first opening area adjacent to the first support portion and a second opening area adjacent to the first support portion, and along the first direction, a minimum distance between the first support portion and the first opening area is D1, a minimum distance between the first support portion and the second opening area is D2, and D1≠D2. The first direction is perpendicular to a thickness direction of the display substrate.

In some embodiments of the present disclosure, the support portions further include a second support portion, along the first direction, the first opening area is located between the first support portion and the second support portion, a distance between the second support portion and the first opening area is D3, and D1≠D3.

In some embodiments of the present disclosure, one of the support portions is provided on a surface of the pixel definition portions away from the display substrate.

In some embodiments of the present disclosure, the pixel definition portions are arranged in one-to-one correspondence with the support portions.

In some embodiments of the present disclosure, the display panel further includes a first light-shielding layer. The first light-shielding layer is located on a side of the support layer away from the pixel definition layer. The first light-shielding layer includes a plurality of first light-shielding portions arranged at intervals, the first light-shielding portions at least partially cover the support portions, and at least one the first light-shielding portions includes a first predetermined light-shielding portion. Along the first direction, the first opening area and the second opening area are located at two sides of the first predetermined light-shielding portion and are adjacent to the first predetermined light-shielding portion, and along the first direction, a minimum distance between the first predetermined light-shielding portion and the first opening area is L1, a minimum distance between the first predetermined light-shielding portion and the second opening area is L2, and L1≠L2. Orthographic projections of the first light-shielding portions on the display substrate at least partially overlap with orthographic projections of the pixel definition portions on the display substrate.

In some embodiments of the present disclosure, L1=D1 and/or L2=D2.

In some embodiments of the present disclosure, L1≠D1 and/or L2≠D2.

In some embodiments of the present disclosure, the first light-shielding portions further include a second predetermined light-shielding portion, and along the first direction, the first opening area is located between the first predetermined light-shielding portion and the second predetermined light-shielding portion, a distance between the second predetermined light-shielding portion and the first opening area is L3, and L1≠L3.

In some embodiments of the present disclosure, the orthographic projections of the first light-shielding portions on the display substrate cover orthographic projections of the support portions on the display substrate.

In some embodiments of the present disclosure, the display panel further includes an encapsulation layer. The encapsulation layer is located between the first light-shielding layer and the support layer.

In some embodiments of the present disclosure, the display panel further includes a first organic layer and a second organic layer. The first organic layer is located on a side of the support layer away from the display substrate. The second organic layer is located on a side of the first organic layer away from the light-emitting layer, and a refractive index of the second organic layer is greater than a refractive index of the first organic layer.

In some embodiments of the present disclosure, two ends of the second organic layer have different minimum distances from a center of the sub-pixels.

In some embodiments of the present disclosure, the first organic layer includes a plurality of first organic layer openings arranged at intervals, and orthographic projections of the first organic layer openings on the display substrate overlap with orthographic projection of the opening area on the display substrate.

In some embodiments of the present disclosure, a surface of the first organic layer openings facing the display substrate is a concave surface, and a surface of the second organic layer close to the display substrate is a convex surface.

In some embodiments of the present disclosure, the display panel further includes a third organic layer. The third organic layer is located at a portion of a surface of the second organic layer away from the first organic layer, and a refractive index of the third organic layer is greater than the refractive index of the second organic layer.

In some embodiments of the present disclosure, an orthographic projection of the third organic layer on the display substrate at least partially overlaps with orthographic projections of the sub-pixels on the display substrate.

In some embodiments of the present disclosure, the third organic layer includes a first organic portion and a second organic portion, an orthographic projection of the first organic portion on the display substrate at least partially overlaps with orthographic projections of the sub-pixels on the display substrate, an orthographic projection of the second organic portion on the display substrate at least partially overlaps with the orthographic projections of the sub-pixels on the display substrate, the orthographic projection of the first organic portion on the display substrate does not overlap with the orthographic projection of the second organic portion on the display substrate, and a refractive index of the first organic portion is less than a refractive index of the second organic portion.

In some embodiments of the present disclosure, a surface of the first organic portion away from the second organic layer is a convex surface, and a surface of the second organic portion away from the second organic layer is a convex surface.

In some embodiments of the present disclosure, the display panel further includes a fourth organic layer. The fourth organic layer is located at a side of the third organic layer away from the second organic layer.

In some embodiments of the present disclosure, the display panel further includes a second light-shielding layer. The second light-shielding layer is located between the fourth organic layer and the first organic layer, the second light-shielding layer includes a plurality of second light-shielding portions arranged at intervals, one of the second light-shielding portions is correspondingly provided at a surface of one of the support portions away from the display substrate, at least part of the second light-shielding portions have different minimum distances from two adjacent opening areas. Orthographic projections of the second light-shielding portions on the display substrate at least partially overlaps with orthographic projections of the pixel definition portions on the display substrate.

To achieve the above purpose, an aspect of the present disclosure provides a display apparatus, including the display panel according to any one of the above embodiments.

### BRIEF DESCRIPTION OF DRAWINGS

The drawings constituting a part of the present disclosure are used to provide a further understanding of the present disclosure. The exemplary embodiments of the present disclosure and the descriptions thereof are used to explain the present disclosure and do not constitute an improper limitation of the present disclosure. In the drawings:

FIG. 1 is a structural schematic diagram of a display panel according to some embodiments of the present disclosure;

FIG. 2 is a structural schematic diagram of a display panel according to some embodiments of the present disclosure;

FIG. 3 is a structural schematic diagram of a further display panel according to some embodiments of the present disclosure;

FIG. 4 is a structural schematic diagram of a further display panel according to some embodiments of the present disclosure;

FIG. 5 is a structural schematic diagram of a display panel according to some embodiments of the present disclosure;

FIG. 6 is a structural schematic diagram of a display panel according to some embodiments of the present disclosure;

FIG. 7 is a structural schematic diagram of a further display panel according to some embodiments of the present disclosure;

FIG. 8 is a structural schematic diagram of a display panel according to some embodiments of the present disclosure;

FIG. 9 is a structural schematic diagram of a display panel according to some embodiments of the present disclosure;

FIG. 10 is a structural schematic diagram of a further display panel according to some embodiments of the present disclosure;

FIG. 11 is a structural schematic diagram of a further display panel according to some embodiments of the present disclosure;

FIG. 12 is a structural schematic diagram of a display panel according to some embodiments of the present disclosure;

FIG. 13 is a structural schematic diagram of a further display panel according to some embodiments of the present disclosure

FIG. 14 is a structural schematic diagram of a further display panel according to some embodiments of the present disclosure

FIG. 15 is a structural schematic diagram of a further display panel according to some embodiments of the present disclosure;

FIG. 16 is a structural schematic diagram of a display panel according to some embodiments of the present disclosure; and

FIG. 17 is a structural schematic diagram of a display apparatus according to some embodiments of the present disclosure.

The drawings include the following reference signs: 10-display panel; 20-pixel definition portion; 30-light-emitting layer; 31-pixel unit; 40-support portion; 401-first support portion; 402-second support portion; 50-opening area; 501-first opening area; 502-second opening area; X1-first direction; 60-first light-shielding portion; 601-first predetermined light-shielding portion; 602-second predetermined light-shielding portion; 70-encapsulation layer; 71-first organic layer; 72-second organic layer; 73-third organic layer; 731-first organic portion; 732-second organic portion; 74-fourth organic layer; 80-second light-shielding portion; 100-display panel.

### DESCRIPTION OF EMBODIMENTS

It should be noted that, in the absence of conflict, embodiments of the present disclosure and these features in the embodiments can be combined with each other. The present disclosure will be described in detail below with reference to the drawings and in conjunction with these embodiments.

In order to enable those skilled in the art to better understand the technical solutions of the present disclosure, the technical solutions of embodiments of the present disclosure will be clearly and completely described below in conjunction with the drawings corresponding to these embodiments of the present disclosure. It is appreciated that the described embodiments are just some, rather than all, of embodiments of the present disclosure. According to embodiments of the present disclosure, all other embodiments obtained by those skilled in the art without any creative effort shall fall within the protection scope of the present disclosure.

It should be noted that the terms “first”, “second”, etc. in the specification, claims and the drawings of the present disclosure are used to distinguish similar objects, and are not used to describe a specific order or sequence. It should be understood that the data used in this way can be interchanged in appropriate circumstances n order to facilitate describing embodiments of the present disclosure herein. In addition, the terms “include” and “have”, as well as any variations thereof, are intended to cover non-exclusive inclusions, for example, a process, method, system, product, or device that includes a series of steps or elements is not necessarily limited to those steps or elements that are explicitly listed, but may include other steps or elements that are not explicitly listed or that are inherent to such process, method, product, or device.

In order to improve the anti-peeping effect of the display panel and improve the light emission at a specific viewing angle, the present disclosure provides a display panel and a display apparatus.

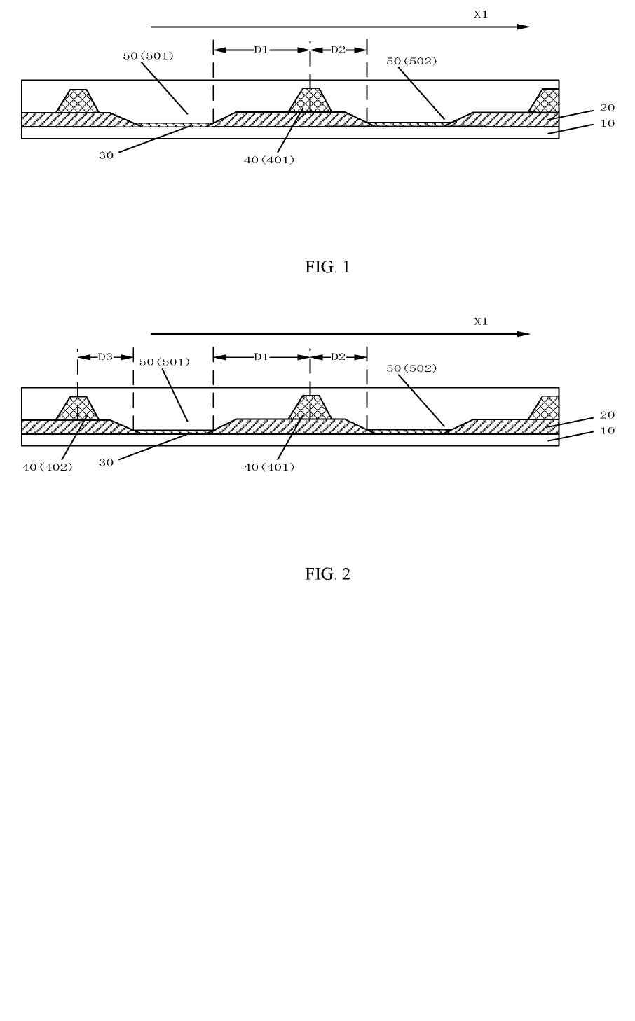

FIG. 1 is a structural schematic diagram of a display panel according to some embodiments of the present disclosure. As shown in FIG. 1, FIG. 2, and FIG. 5 to FIG. 7, the display panel includes: a display substrate 10, a pixel definition layer, a plurality of sub-pixels, and a support layer.

The pixel definition layer is provided at a side of the display substrate 10, and includes a plurality of pixel definition portions 20, and an opening area 50 is provided between two adjacent pixel definition portions 20.

In some embodiments of the present disclosure, the pixel definition layer is configured to define the specific position of a light-emitting layer 30, i.e., the specific positions of the sub-pixels. The colors of two adjacent sub-pixels can be the same or different.

The sub-pixel includes the light-emitting layer 30, and the light-emitting layer 30 is at least partially located in the opening area 50.

In practical applications, the light-emitting layer 30 may completely fill the opening area 50, or partially fill the opening area 50. That is, the orthographic projection of the light-emitting layer 30 on the display substrate 10 partially overlaps with the orthographic projection of the opening area 50 on the display substrate 10, or completely overlaps with the orthographic projection of the opening area 50 on the display substrate 10.

The support layer is located at a side of the light-emitting layer 30 away from the display substrate 10, and includes a plurality of support portions 40. The support portions 40 are located on a side of the pixel definition portions 20 away from the display substrate 10. The support portions 40 includes a first support portion 401.

In practical applications, the support layer is configured to support and maintain a fixed distance between the array substrate and the color filter substrate of the display panel. The material of the support layer may be a photoresist material. It should be noted that the plurality of support portions 40 include a main column and an auxiliary column. The main column is the support portion 40 that always works under the normal working environment of the display panel, and the auxiliary column is configured to increase the overall support strength of the support layer by supporting the array substrate when the display panel is accidentally subjected to external pressure, so as to prevent the display panel from being damaged by external pressure. Those skilled in the art can set the support layer by comprehensively considering factors such as the density, thickness, height, step difference and compression rate of the material of the support layer to achieve the optimal display effect. In addition, the thickness of the support layer is greater than the thickness of the pixel definition layer. The cross-section shape of each support portion 40 along the first direction X1 may be trapezoidal as shown in FIG. 1, or semi-circular or rectangular.

Along the first direction X1, the opening area 50 includes a first opening area 501 adjacent to the first support portion 401 and a second opening area 502 adjacent to the first support portion 401. Along the first direction X1, the minimum distance between the first support portion 401 and the first opening area 501 is D1, the minimum distance between the first support portion 401 and the second opening area 502 is D2, and D1≠D2. The first direction X1 is perpendicular to the thickness direction of the display substrate 10.

In some embodiments of the present disclosure, the first opening area 501 and the second opening area 502 are located at two sides of the first support portion 401, and the first opening area 501 and the second opening area 502 are adjacent to the first support portion 401. D1 and D2 are the minimum distances from the same point of the first support portion 401 to the end of the first opening area 501 close to the first support portion 401 and to the end of the second opening area 502 close to the first support portion 401 in the first direction X1, respectively, and the point can be located on the central axis of the first support portion 401 in a second direction. D1 may be greater than D2, and D1 may also be less than D2. D1≠D2, which indicates that, in the second direction, the central axis of the first support portion 401 and the central axis of the corresponding pixel definition portion 20 are not on the same straight line. The second direction is perpendicular to the first direction X1, and the second direction is the thickness direction of the display substrate 10.

For the display panel according to these above embodiments, the minimum distance between the first support portion and the first opening area is not equal to the minimum distance between the first support portion and the second opening area, the angle between the light emitted from the first opening area and the plane of the light-emitting layer is a first angle, and the angle between the light emitted from the second opening area and the plane of the light-emitting layer is a second angle. Therefore, the first angle is not equal to the second angle. In addition, the first support portion is provided on the pixel definition portions, which can shield the large-viewing angle light emitted from the first opening area and the second opening area, and can achieve differentiated light emission from the first opening area and the second opening area in different directions and positions, so as to improve the differentiated anti-peeping effect of the display panel, and solve the technical problem how to improve the differentiated anti-peeping effect of the display panel in the prior art.

In a further embodiment of the present disclosure, as shown in FIG. 2, the support portions 40 further includes a second support portion 402. The second support portion 402 is a support portion 40 adjacent to the first support portion 401 among the plurality of support portions 40. Along the first direction X1, the first opening area 501 is located between the first support portion 401 and the second support portion 402, the first support portion 401 and the second support portion 402 are located at two sides of the first opening area 501, and the first support portion 401 and the second support portion 402 are both adjacent to the first opening area 501. The distance between the second support portion 402 and the first opening area 501 is D3. That is, D3 is the minimum distance between the second support portion 402 and the end of the first opening area 501 close to the second support portion 402, and D1≠D3. Since the minimum distance between the first support portion 401 and the first opening area 501 is not equal to the minimum distance between the second support portion 402 and the first opening area 501, the angle between the light emitted from the first opening area 501 towards the direction of the first support portion 401 and the plane of the light-emitting layer 30 is a third angle, and the angle between the light emitted from the first opening area 501 towards the direction of the second support portion 402 and the plane of the light-emitting layer 30 is a fourth angle, the third angle is different from the fourth angle, which can achieve differentiated light emission from the first opening area 501 in different directions, and further improve the differentiated anti-peeping effect of the display panel.

In some embodiments of the present disclosure, in addition to D1 shown in FIG. 1 and FIG. 2, D1 can also be the minimum distance between the central axis of the first support portion 401 and the central axis of the first opening area 501 along the first direction X1. In addition to D3 shown in FIG. 2, D3 can also be the minimum distance between the central axis of the second support portion 402 and the central axis of the first opening area 501 along the first direction X1. D1 can be greater than D3, and D1 can also be less than D3. D1≠D3, which indicates that in the second direction, the central axis of the second support portion 402 and the central axis of the corresponding pixel definition portion 20 are not on the same straight line. In some embodiments of the present disclosure, along the first direction X1, the second opening area 502 is located between the first support portion 401 and the second support portion 402, the distance between the second support portion 402 and the second opening area 502 is D3, and D2≠D3. Since the minimum distance between the first support portion 401 and the second opening area 502 is not equal to the minimum distance between the second support portion 402 and the second opening area 502, the angle between the light emitted from the second opening area 502 towards the direction of the first support portion 401 and the plane of the light-emitting layer 30 is the fifth angle, and the angle between the light emitted from the second opening area 502 towards the direction of the second support portion 402 and the plane of the light-emitting layer 30 is the sixth angle, the fifth angle is different from the sixth angle, which can achieve differentiated light emission from the second opening area 502 in different directions, and further improve the differentiated anti-peeping effect of the display panel.

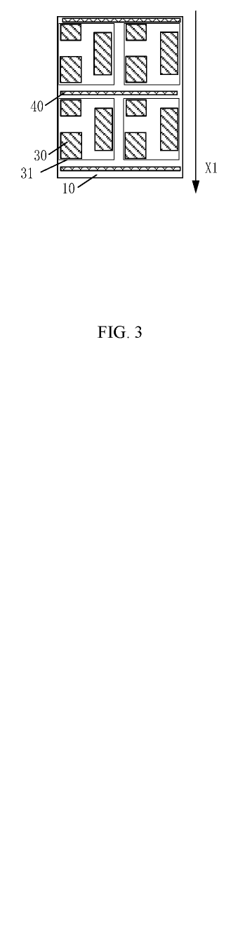

In a further embodiment of the present disclosure, as shown in FIG. 3, one of the support portions 40 is provided on a surface of the pixel definition portions away from the display substrate 10. Among the plurality of pixel definition portions, the support portions 40 are provided on the surface of some pixel definition portions away from the display substrate 10, that is, there are the plurality of sub-pixels between two adjacent support portions 40 along the first direction X1, and the colors of the plurality of light-emitting layers 30 are different. Since the sub-pixels include the light-emitting layers 30, one of the light-emitting layers 30 can represent one sub-pixel, and three adjacent sub-pixels constitute a pixel unit 31. In other words, along the first direction X1, the support portions 40 are provided on both sides of each pixel unit 31, which can further effectively reduce the large-viewing angled light emission of the pixels, and further improve the differentiated anti-peeping effect of the display panel.

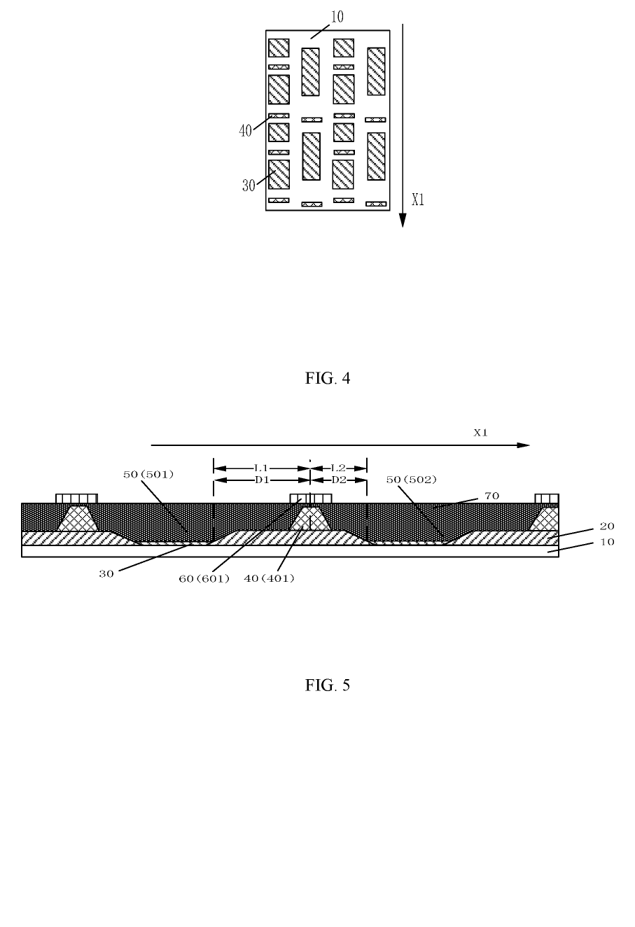

In order to further improve the differentiated anti-peeping effect of the display panel, as shown in FIG. 4, in some embodiments of the present disclosure, the pixel definition portions are arranged in one-to-one correspondence with the support portions 40. That is, the support portion 40 is provided at the side of each of the pixel definition portions away from the display substrate 10. Along the first direction X1, since the sub-pixels include the light-emitting layers 30, one of the light-emitting layers 30 can represent one sub-pixel, and the support portions 40 are provided at two sides of each sub-pixel. Within a unit area, the density of the support portions 40 is greater, which can further effectively reduce the large-viewing angled light emission of the sub-pixels, and further improve the differentiated anti-peeping effect of the display panel.

In some embodiments of the present disclosure, the specific positions of the support portions 40 are not limited to the positions shown in FIG. 3 and FIG. 4. Those skilled in the art can set the positions of the support portions 40 according to actual conditions and light emission requirements, which will not be elaborated herein.

In a further embodiment of the present disclosure, as shown in FIG. 5, the display panel further includes a first light-shielding layer. The first light-shielding layer is located at a side of the support layer away from the pixel definition layer. The first light-shielding layer includes a plurality of first light-shielding portions 60 that are arranged at intervals, and the first light-shielding portions 60 at least partially cover the support portions 40. In the first direction X1, the average width of the first light-shielding portions 60 is greater than or equal to the minimum width of the support portions 40. The first light-shielding portions 60 include a first predetermined light-shielding portion 601, and the first predetermined light-shielding portion 601 can be any one of the first light-shielding portions 60. Along the first direction X1, the first opening area 501 and the second opening area 502 are located at both sides of the first predetermined light-shielding portion 601, and are adjacent to the first predetermined light-shielding portion 601. Along the first direction X1, the minimum distance between the first predetermined light-shielding portion 601 and the first opening area 501 is L1, the minimum distance between the first predetermined light-shielding portion 601 and the second opening area 502 is L2, L1 and L2 are the minimum distances from the same point of the first predetermined light-shielding portion 601 to the end of the first opening area 501 close to the first predetermined light-shielding portion 601 and to the end of the second opening area 502 close to the first predetermined light-shielding portion 601 in the first direction X1, respectively, and the point can be located on the central axis of the first predetermined light-shielding portion 601 in the second direction. L1≠L2, L1 may be greater than L2, and L1 may also be less than L2. L1≠L2, which indicates that in the second direction, the central axis of the first predetermined light-shielding portion 601 and the central axis of the corresponding pixel definition portion are not on the same straight line. Orthographic projections of the first light-shielding portions 60 on the display substrate at least partially overlap with orthographic projections of the pixel definition portions on the display substrate. In the first direction X1, the average width of the first light-shielding portions 60 is less than or equal to the minimum width of the pixel definition portions. The minimum distance between the first predetermined light-shielding portion 601 and the first opening area 501 is not equal to the minimum distance between the first predetermined light-shielding portion 601 and the second opening area 502. Therefore, the first angle is not equal to the second angle. The first predetermined light-shielding portion 601 and the first support portion 40 are simultaneously configured as blocking walls for the large-viewing angled light emitted from the first opening area 501 and the second opening area 502, which can achieve differentiated light emission of the first opening area 501 and the second opening area 502 in different directions and positions, and further improve the differentiated anti-peeping effect of the display panel.

In some embodiments of the present disclosure, the first light-shielding layer can be a black matrix (referred to as BM). Generally, the BM is located at the outermost side of the display panel, i.e., the black edge portion of the display apparatus, and is configured to prevent the internal light from leaking out from the edge of the display panel. Therefore, the width of the first light-shielding portions should not be too narrow. In addition, when the colors of the sub-pixels corresponding to the two adjacent light-emitting layers are different, the first light-shielding portions can also be configured to separate the light-emitting layers and enhance the color contrast of the sub-pixels. In practical applications, the material of the first light-shielding layer may be organic material or inorganic material.

In order to further improve the differentiated anti-peeping effect of the display panel, as shown in FIG. 5, L1=D1 and/or L2=D2. That is, in the second direction, the central axis of the first predetermined light-shielding portion 601 coincides with the central axis of the first support portion 401. The first predetermined light-shielding portion 601 and the first support portion 401 are simultaneously configured as blocking walls for the large-viewing angled light emitted from the first opening area 501 and the second opening area 502, and the first predetermined light-shielding portion 601 and the first support portion 401 have the same shielding effect on the light emitted from the first opening area 501 and the light emitted from the second opening area 502, so as to further improve the differentiated anti-peeping effect of the display panel.

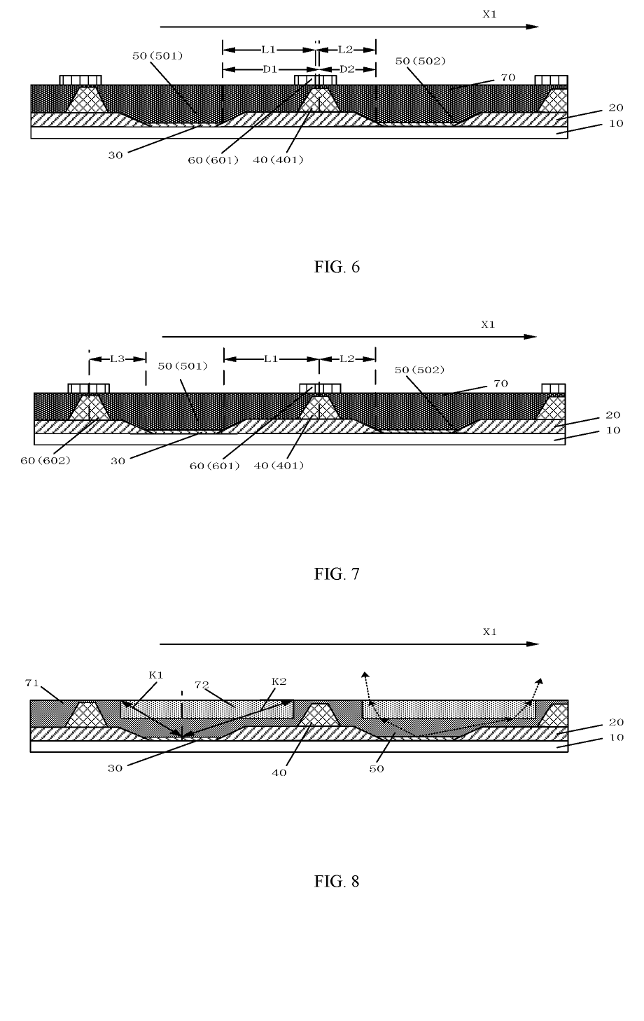

In a further embodiment of the present disclosure, as shown in FIG. 6, L1≠D1 and/or L2≠D2. That is, in the second direction, the central axis of the first predetermined light-shielding portion 601 does not coincide with the central axis of the first support portion 401. The first predetermined light-shielding portion 601 and the first support portion 401 are simultaneously configured as blocking walls for the large-viewing angled light emitted from the first opening area 501 and the second opening area 502, and the first predetermined light-shielding portion 601 and the first support portion 401 have different shielding effects on the light emitted from the first opening area 501 and the light emitted from the second opening area 502, which further meet various light emission requirements, and further improve the diversity of differentiated anti-peeping effects of the display panel.

In some embodiments of the present disclosure, L1 can be greater than D1, or L1 can be less than D1. L2 can be greater than D2, or L2 can be less than D2. In addition, the sum of L1 and L2 and the sum of D1 and D2 are the widths of the corresponding pixel definition portions in the first direction, respectively.

In a further embodiments of the present disclosure, as shown in FIG. 7, the first light-shielding portions 60 further include a second predetermined light-shielding portion 602. The second predetermined light-shielding portion 602 is the one of the plurality of first light-shielding portions 60 adjacent to the first predetermined light-shielding portion 601. Along the first direction X1, the first opening area 501 is located between the first predetermined light-shielding portion 601 and the second predetermined light-shielding portion 602, the first predetermined light-shielding portion 601 and the second predetermined light-shielding portion 602 are located at two sides of the first opening area 501, and the first predetermined light-shielding portion 601 and the second predetermined light-shielding portion 602 are both adjacent to the first opening area 501. The distance between the second predetermined light-shielding portion 602 and the first opening area 501 is L3. That is, L3 is the minimum distance between the second predetermined light-shielding portion 602 and the end of the first opening area 501 close to the second predetermined light-shielding portion 602, and L1≠L3. Since the minimum distance between the first predetermined light-shielding portion 601 and the first opening area 501 is not equal to the minimum distance between the second predetermined light-shielding portion 602 and the first opening area 501, the angle between the light emitted from the first opening area 501 towards the direction of the first predetermined light-shielding portion 601 and the plane of the light-emitting layer 30 is a seventh angle, and the angle between the light emitted from the first opening area 501 towards the direction of the second predetermined light-shielding portion 602 and the plane of the light-emitting layer 30 is an eighth angle, the seventh angle is different from the eighth angle, which can achieve differentiated light emission from the first opening area 501 in different directions, and further improve the differentiated anti-peeping effect of the display panel.

In some embodiments of the present disclosure, in addition to L1 shown in FIG. 5 and FIG. 6, L1 can also be the minimum distance between the central axis of the first predetermined light-shielding portion 601 and the central axis of the first opening area 501 along the first direction X1. In addition to L3 shown in FIG. 7, L3 can also be the minimum distance between the central axis of the second predetermined light-shielding portion 602 and the central axis of the first opening area 501 along the first direction X1. L1 may be greater than L3, or L1 may be less than L3. L1≠L3, which indicates that, in the second direction, the central axis of the second predetermined light-shielding portion 602 and the central axis of the corresponding pixel definition portion are not on the same straight line.

In some embodiments of the present disclosure, as shown in FIG. 7, the orthographic projection of the first light-shielding portion 60 on the display substrate covers the orthographic projection of the support portion 40 on the display substrate. That is, the maximum width of the first light-shielding portion 60 is greater than the maximum width of the support portion 40. In practical applications, the actual light emission from the display panel depends more on the blocking wall effect of the first light-shielding layer, and the support layer plays an auxiliary role. Therefore, the above arrangement can further improve the light-shielding effect of the first light-shielding layer, and further improve the differentiated anti-peeping effect of the display panel.

In order to further improve the stability of the display panel, as shown in FIG. 5 to FIG. 7, the display panel further includes an encapsulation layer 70. The encapsulation layer 70 is located between the first light-shielding layer and the support layer. The encapsulation layer 70 can impede the invasion of water and oxygen into the light-emitting layer, improve the encapsulation effect of the display panel, protect the light-emitting layer 30 from erosion, and further extend the lifespan of the display panel.

In practical applications, the encapsulation layer can be a single-layer structure or a multi-layer structure. The material of the encapsulation layer can be organic material or inorganic material. In some embodiments of the present disclosure, the encapsulation layer can be composed of organic material layers and inorganic material layers that are alternately stacked, thereby improving the encapsulation effect of the encapsulation layer.

In some embodiments of the present disclosure, as shown in FIG. 8, the display panel further includes a first organic layer 71 and a second organic layer 72. The first organic layer 71 is located at a side of the support layer away from the display substrate 10. The first organic layer 71 fills the opening areas 50 between adjacent pixel definition portions 20 and between adjacent support portions 40, and the first organic layer 71 is further located on a surface of the support portions 40 away from the pixel definition portions 20. That is, the maximum thickness of the first organic layer 71 is greater than the sum of the maximum thickness of the pixel definition portions 20 and the maximum thickness of the support portions 40. The second organic layer 72 is located at a side of the first organic layer 71 away from the light-emitting layer 30, and the material of the first organic layer 71 is different from the material of the second organic layer 72. The refractive index of the second organic layer 72 is greater than the refractive index of the first organic layer 71. Therefore, in the process of the light emitted by the light-emitting layer 30 entering the second organic layer 72 from the first organic layer 71, the refraction angle decreases, so as to further improve the focusing effect. Meanwhile, due to the fact that D1≠D2, the angles of the light reaching the interfaces of the first organic layer 71 and the second organic layer 72 are different, and the angles of the emitted light, after being refracted by the second organic layer 72, are also different, which can achieve differentiated light emission from the opening area 50 in different directions, and further improve the differentiated anti-peeping effect of the display panel.

In some embodiments of the present disclosure, the materials of the first organic layer and the second organic layer can be one or more of epoxy resin, acrylic resin, polycarbonate, silicone rubber, polyurethane and polyimide. Those skilled in the art can choose the materials according to actual needs, which will not be elaborated herein.

As shown in FIG. 8 to FIG. 16, the minimum distances between the two ends of the second organic layer 72 and the center of the sub-pixels are different. Since K1≠K2, the angles at which the light emitted by the sub-pixels reaches two ends of the second organic layer 72 are also different, which can achieve differentiated light emission from the opening area 50 in different directions, and further improve the differentiated anti-peeping effect of the display panel. It should be noted that the specific positions of the pixel definition portions 20 and the support portions 40 are the same as those in FIG. 1, which will not be elaborated herein.

In some embodiments of the present disclosure, as shown in FIG. 8 to FIG. 16, along the second direction, the central axis of the second organic layer 72 is not in the same straight line as the central axis of the light-emitting layer 30. The minimum distance between the first end of the second organic layer 72 and the center of the sub-pixels is K1, the minimum distance between the second end of the second organic layer 72 and the center of the sub-pixels is K2, and K1≠K2. K1 may be greater than K2, or K1 may be less than K2.

In some embodiments of the present disclosure, as shown in FIG. 8 to FIG. 16, the first organic layer 71 includes a plurality of first organic layer openings arranged at intervals. In practical applications, since the thickness of the support layer is much greater than the thickness of the pixel definition layer and the organic material has a leveling property, during the deposition of the first organic layer 71, the first organic layer openings are formed at positions corresponding to the opening areas 50. The average thickness of the first organic layer openings is related to the average thickness of the sub-pixels, the average thickness of the pixel definition layers, and the average thickness of the support layers. The orthographic projections of the first organic layer openings on the display substrate overlaps with the orthographic projection of the opening area 50 on the display substrate. In practical applications, the orthographic projections of the first organic layer openings on the display substrate can partially overlap with the orthographic projection of the opening area 50 on the display substrate, or completely overlap with the orthographic projection of the opening area 50 on the display substrate. The second organic layer 72 is located in the first organic layer openings, and the surface of the second organic layer 72 away from the first organic layer 71 is flush with the top of the first organic layer openings.

In some embodiments of the present disclosure, the specific shape of the first organic layer openings is not limited in the present disclosure. The shape of the bottom of the first organic layer openings may be a straight line or a curve.

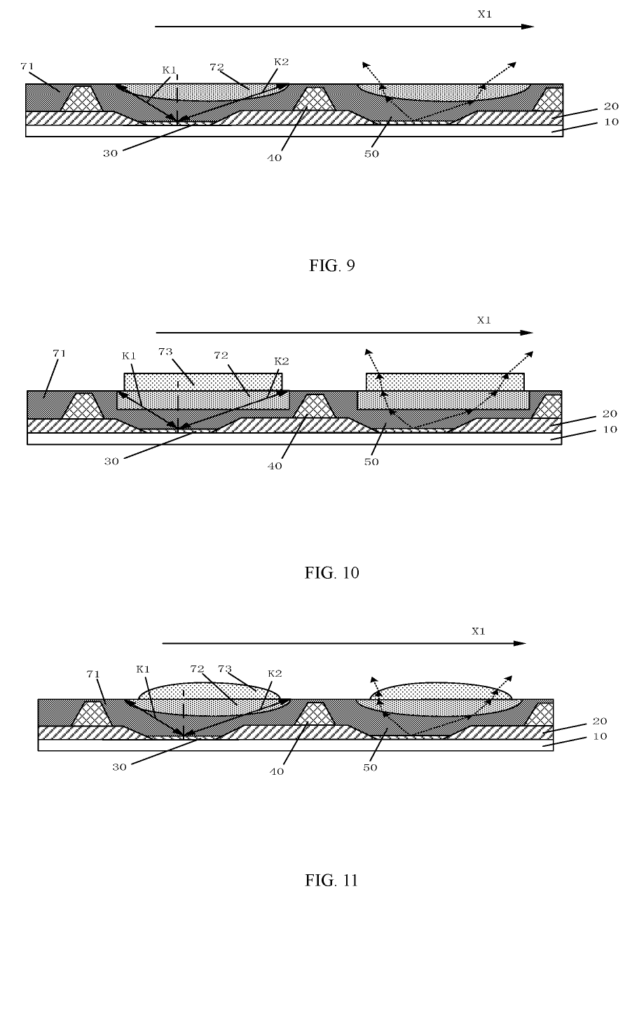

In some embodiments of the present disclosure, as shown in FIG. 9, the surface of the opening of the first organic layer 71 facing the display substrate 10 is a concave surface, the bottom surface of the opening of the first organic layer 71 protrudes towards the display substrate 10, and the distance from the bottom of the opening of the first organic layer 71 to the display substrate 10 is smaller than the distance from the edge of the opening of the first organic layer 71 to the display substrate 10. The surface of the second organic layer 72 close to the display substrate 10 is a convex surface. The surface of the second organic layer 72 close to the display substrate 10 protrudes towards the display substrate 10. Since the first organic layer 71 and the second organic layer 72 form corresponding concave-convex structures, the second organic layer 72 can form a semi-convex lens, which can reduce the refraction angle of the light-emitting layer, and further improve the focusing effect.

In some embodiments of the present disclosure, the concave surface of the first organic layer and the convex surface of the second organic layer may be fully matched or partially matched. When the concave surface of the first organic layer and the convex surface of the second organic layer are fully matched, the optical loss of light during the transmission from the first organic layer to the second organic layer can be reduced.

In a further embodiment of the present disclosure, as shown in FIG. 10 and FIG. 11, the display panel further includes a third organic layer 73. The third organic layer 73 is located at a portion of the surface of the side of the second organic layer 72 away from the first organic layer 71. The materials of the third organic layer 73 and the second organic layer 72 are different. The refractive index of the third organic layer 73 is greater than the refractive index of the second organic layer 72. Therefore, in the process of light entering the third organic layer 73 from the second organic layer 72, the refraction angle decreases, so as to further improve the focusing effect. Since D1≠D2, the angles of the light reaching the interfaces of the first organic layer 71 and the second organic layer 72 are different, and the angles of the emitted light, after being refracted by the second organic layer 72 and the third organic layer 73, are also different, which can achieve differentiated light emission from the opening area 50 in different directions, and further improve the differentiated anti-peeping effect of the display panel.

In some embodiments of the present disclosure, the materials of the third organic layer may be one or more of epoxy resin, acrylic resin, polycarbonate, silicone rubber, polyurethane and polyimide. Those skilled in the art can choose the materials according to actual needs, which will not be elaborated herein.

In some embodiments of the present disclosure, as shown in FIG. 10 and FIG. 11, the orthographic projection of the third organic layer 73 on the display substrate 10 at least partially overlaps with the orthographic projection of the sub-pixel on the display substrate 10. The above arrangement can ensure that at least part of the light emitted by the sub-pixels can be refracted by the first organic layer 71, the second organic layer 72 and the third organic layer 73 in sequence to achieve the adjustment of the refraction angle. After being refracted by the first organic layer 71, the second organic layer 72 and the third organic layer 73, the angles of the emitted light are also different, which can achieve differentiated light emission from the opening area 50 in different directions, and further improve the differentiated anti-peeping effect of the display panel.

In some embodiments of the present disclosure, the orthographic projection of the third organic layer 73 on the display substrate 10 completely overlaps with the orthographic projection of the sub-pixel on the display substrate 10, or the orthographic projection of the third organic layer 73 on the display substrate 10 completely overlaps with the orthographic projection of the second organic layer 72 on the display substrate 10.

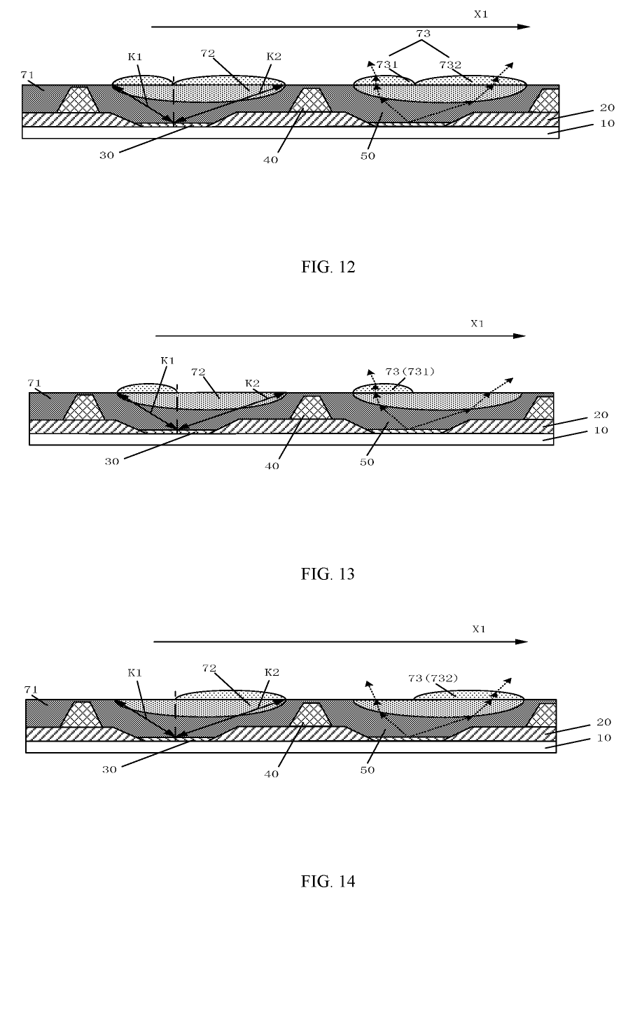

In some embodiments of the present disclosure, as shown in FIG. 12, the third organic layer 73 includes a first organic portion 731 and a second organic portion 732, and the materials of the first organic portion 731 and the second organic portion 732 are different. The orthographic projection of the first organic portion 731 on the display substrate 10 at least partially overlaps with the orthographic projection of the sub-pixel on the display substrate 10, and the arrangement can ensure that at least part of the light emitted by the sub-pixels can be refracted by the first organic layer 71, the second organic layer 72 and the first organic portion 731 in sequence to achieve the adjustment of the refraction angle. The orthographic projection of the second organic portion 732 on the display substrate 10 at least partially overlaps with the orthographic projection of the sub-pixel on the display substrate 10, and the arrangement can ensure that at least part of the light emitted by the sub-pixels can be refracted by the first organic layer 71, the second organic layer 72 and the second organic portion 732 in sequence to achieve the adjustment of the refraction angle. The orthographic projection of the first organic portion 731 on the display substrate 10 does not overlap with the orthographic projection of the second organic portion 732 on the display substrate 10, and the refractive index of the first organic portion 731 is less than the refractive index of the second organic portion 732. The arrangement can reduce the refraction angle of the large-viewing angled light emitted to the first organic portion 731 and reduce the refraction angle of the large-viewing angled light emitted to the second organic portion 732. Since the refractive index of the first organic portion 731 is less than the refractive index of the second organic portion 732, the refraction angle of the large-viewing angle light emitted to the second organic portion 732 is reduced more, so that the angle of the light emitted from the second organic portion 732 can be greater than the angle of the light emitted from the first organic portion 731. Therefore, the angles of the emitted light are not the same, which can achieve differentiated light emission from the opening area 50 in different directions, and further improve the differentiated anti-peeping effect of the display panel.

In some embodiments of the present disclosure, the first organic portion 731 and the second organic portion 732 can be arranged at two sides of the central axis of the light-emitting layer 30, respectively. In an embodiment of the present disclosure, as shown in FIG. 13, the third organic layer 73 includes only the first organic portion 731. As shown in FIG. 14, the third organic layer 73 includes only the second organic portion 732. When the third organic layer 73 includes only either of the first organic portion 731 and the second organic portion 732, the manufacturing process can be further reduced, thereby further reducing the manufacturing cost of the display panel.

In some further embodiments of the present disclosure, as shown in FIG. 12, the surface of the first organic portion 731 away from the second organic layer 72 is a convex surface. Therefore, the first organic portion 731 can form a semi-convex lens, and the second organic layer 72 can also form a semi-convex lens. The first organic portion 731 and the second organic layer 72 are combined to form a convex lens. The surface of the second organic portion 732 away from the second organic layer 72 is a convex surface. Therefore, the second organic portion 732 can form a semi-convex lens, and the second organic layer 72 can also form a semi-convex lens. The second organic portion 732 and the second organic layer 72 are combined to form a convex lens. The convex lens formed by the combination of the first organic portion 731 and the second organic layer 72 can refract the light passing through the first organic layer 71, the second organic layer 72 and the first organic portion 731 in sequence. The convex lens formed by the combination of the second organic portion 732 and the second organic layer 72 can refract the light passing through the first organic layer 71, the second organic layer 72 and the second organic portion 732 in sequence. The above two kinds of convex lenses structures can further improve the focusing effect.

In some embodiments of the present disclosure, the surface of the side of the first organic portion away from the second organic layer is a convex surface, that is, the surface of the side of the first organic portion away from the second organic layer protrudes towards the side away from the display substrate. The surface of the side of the second organic portion away from the second organic layer is a convex surface, that is, the surface of the side of the second organic portion away from the second organic layer protrudes towards the side away from the display substrate.

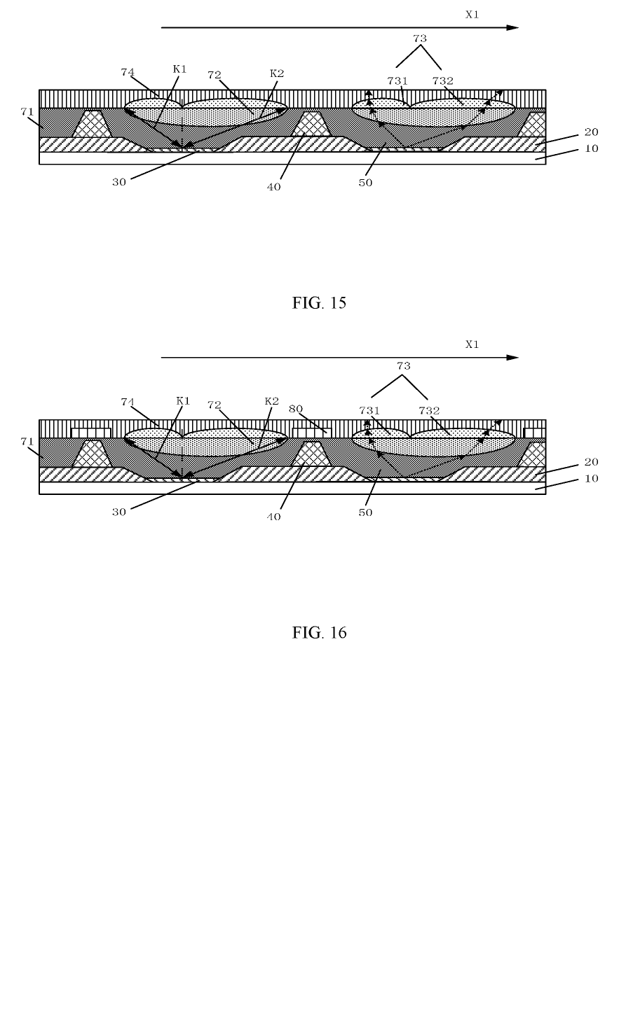

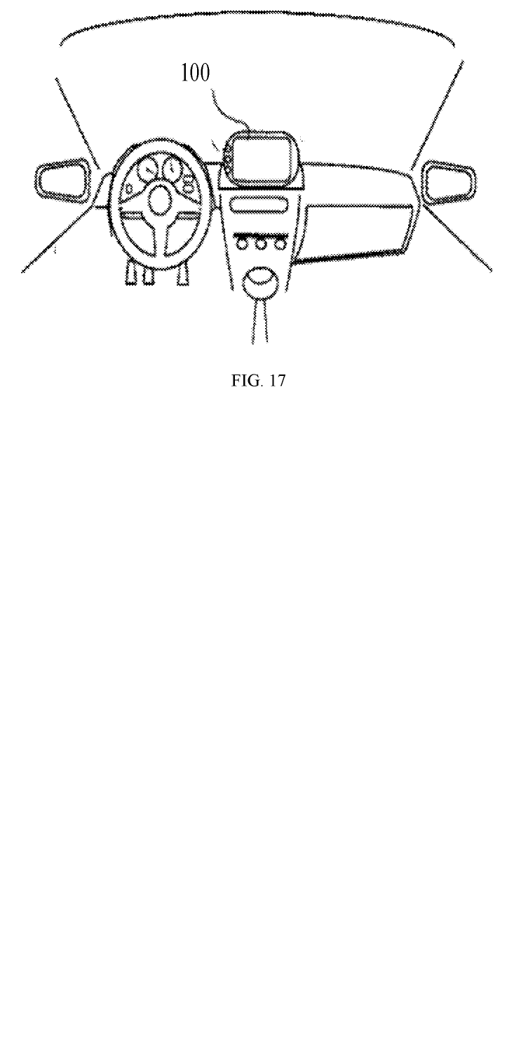

In some further embodiments of the present disclosure, as shown in FIG. 15, the display panel further includes a fourth organic layer 74. The fourth organic layer 74 is located at a side of the third organic layer 73 away from the second organic layer 72. The fourth organic layer 74 is located on the surface of the first organic layer 71 away from the display substrate 10 and on the surface of the third organic layer 73 away from the display substrate 10. The arrangement of the fourth organic layer 74 can further ensure that the light emitted by the sub-pixel can be refracted by the first organic layer 71, the second organic layer 72, the third organic layer 73 and the fourth organic layer 74 in sequence to achieve the adjustment of the refraction angle. After being refracted by the first organic layer 71, the second organic layer 72, the third organic layer 73 and the fourth organic layer 74, the angles of the emitted light are also different. The upward part of the large-viewing angled light is extracted and emitted at an angle approximately perpendicular to the panel, and the downward part of the large-viewing angled light is extracted and emitted at a large angle, which can achieve differentiated light emission from the opening area in different directions, and further improve the differentiated anti-peeping effect of the display panel.

In some embodiments of the present disclosure, the materials of the fourth organic layer can be one or more of epoxy resin, acrylic resin, polycarbonate, silicone rubber, polyurethane and polyimide. Those skilled in the art can choose the materials according to actual needs, which will not be elaborated herein. In addition, the value of the refractive index of the fourth organic layer can be between the refractive indexes of the first organic portion and the second organic portion, that is, the refractive index of the fourth organic layer is greater than the refractive index of the first organic portion and less than the refractive index of the second organic portion.

In some embodiments of the present disclosure, as shown in FIG. 16, the display panel further includes a second light-shielding layer. The second light-shielding layer is located between the fourth organic layer 74 and the first organic layer 71, and includes a plurality of second light-shielding portions 80 that are arranged at intervals. One of the second light-shielding portions 80 is correspondingly provided on a surface of one of the support portions 40 away from the display substrate 10, the second light-shielding portion 80 at least partially covers the support portion 40. In the first direction X1, the average width of the second light-shielding portions 80 is greater than or equal to the minimum width of the support portions 40. At least part of the second light-shielding portions 80 have different minimum distances from two adjacent opening areas 50. Orthographic projections of the second light-shielding portions 80 on the display substrate 10 at least partially overlap with the orthographic projections of the pixel definition portions 20 on the display substrate 10. In the first direction X1, the average width of the second light-shielding portions 80 is less than or equal to the minimum width of the pixel definition portions 20. The refraction angle of the emitted light is reduced through the first organic layer 71 and the second organic layer 72, and the second shading layer is used as a blocking wall for the large-viewing angled light emitted from the opening area 50, so as to achieve differentiated light emission of the opening area 50 in different directions and positions, further improve the differentiated anti-peeping effect of the display panel.

In some embodiments of the present disclosure, the second light-shielding layer can be a black matrix (referred to as BM). Generally, the BM is located at the outermost side of the display panel, i.e., the black edge portion of the display apparatus, and is configured to prevent the internal light from leaking out from the edge of the display panel. Therefore, the width of the second light-shielding portions should not be too narrow. In addition, when the colors of the sub-pixels corresponding to the two adjacent light-emitting layers are different, the second light-shielding portions can also be configured to separate the light-emitting layers and enhance the color contrast of the sub-pixels. In practical applications, the material of the second light-shielding layer may be organic material or inorganic material.

In a further embodiment of the present disclosure, as shown in FIG. 17, provided is a display apparatus, including the display panel 100 according to any one of the above embodiments. The specific structure of the display panel 100 has been described in detail in the above embodiments, which will not be elaborated herein. The display apparatus shown in FIG. 17 is merely for schematic illustration. The display apparatus can be a vehicle-mounted display apparatus as shown in FIG. 17, or can be any electronic equipment with a display function, such as a mobile phone, a tablet computer, a laptop computer, an e-reader, or a television.

As the display apparatus according to embodiments of the present disclosure includes the above display panel, during the use of the display apparatus, the minimum distance between the first support portion and the first opening area is not equal to the minimum distance between the first support portion and the second opening area, the angle between the light emitted from the first opening area and the plane of the light-emitting layer is the first angle, and the angle between the light emitted from the second opening area and the plane of the light-emitting layer is the second angle. Therefore, the first angle is not equal to the second angle. In addition, the first support portion is provided on the pixel definition portions, which can shield the large-viewing angled light emitted from the first opening area and the second opening area, achieve differentiated light emission from the first opening area and the second opening area in different directions and positions, improve the differentiated anti-peeping effect of the display panel, and solve the technical problem how to improve the differentiated anti-peeping effect of the display panel in the prior art.

For the display panel according to present disclosure, the minimum distance between the first support portion and the first opening area is not equal to the minimum distance between the first support portion and the second opening area, the angle between the light emitted from the first opening area and the plane of the light-emitting layer is the first angle, and the angle between the light emitted from the second opening area and the plane of the light-emitting layer is the second angle. Therefore, the first angle is not equal to the second angle. In addition, the first support portion is provided on the pixel definition portions, which can shield the large-viewing angled light emitted from the first opening area and the second opening area, achieve differentiated light emission from the first opening area and the second opening area in different directions and positions, improve the differentiated anti-peeping effect of the display panel, and solve the technical problem how to improve the differentiated anti-peeping effect of the display panel in the prior art.

The display apparatus according to the present disclosure includes a display panel. For the display panel, the minimum distance between the first support portion and the first opening area is not equal to the minimum distance between the first support portion and the second opening area, the angle between the light emitted from the first opening area and the plane of the light-emitting layer is the first angle, and the angle between the light emitted from the second opening area and the plane of the light-emitting layer is the second angle. Therefore, the first angle is not equal to the second angle. In addition, the first support portion is provided on the pixel definition portions, which can shield the large-viewing angled light emitted from the first opening area and the second opening area, achieve differentiated light emission from the first opening area and the second opening area in different directions and positions, the differentiated anti-peeping effect of the display panel, and solve the technical problem how to improve the differentiated anti-peeping effect of the display panel in the prior art.

The above description is merely optional embodiments of the present disclosure, and is not intended to limit the present disclosure. For those skilled in the art, the present disclosure may have various modifications and changes. Any modification, equivalent replacement, improvement, etc. made within the spirit and principle of the present disclosure shall fall within the protection scope of the present disclosure.

What is claimed is:

1. A display panel, comprising:
a display substrate;
a pixel definition layer provided at a side of the display substrate, wherein the pixel definition layer comprises a plurality of pixel definition portions, and an opening area is provided between two adjacent pixel definition portions;
a plurality of sub-pixels, wherein at least one of the plurality of sub-pixels comprises a light-emitting layer, and the light-emitting layer is at least partially located in the opening area; and
a support layer located at a side of the light-emitting layer away from the display substrate, wherein the support layer comprises a plurality of support portions, and the plurality of support portions are located on a side of the plurality of pixel definition portions away from the display substrate, and comprise a first support portion;
wherein, along a first direction, the opening area comprises a first opening area adjacent to the first support portion and a second opening area adjacent to the first support portion, and along the first direction, a minimum distance between the first support portion and the first opening area is D1, and a minimum distance between the first support portion and the second opening area is D2, wherein D1≠D2, and wherein the first direction is perpendicular to a thickness direction of the display substrate.

2. The display panel according to claim 1, wherein the support portions further comprise a second support portion, along the first direction, the first opening area is located between the first support portion and the second support portion, and a distance between the second support portion and the first opening area is D3, wherein D1≠D3.

3. The display panel according to claim 1, wherein one of the support portions is provided on a surface of at least one of the pixel definition portions away from the display substrate.

4. The display panel according to claim 1, wherein the pixel definition portions are arranged in one-to-one correspondence with the support portions.

5. The display panel according to claim 1, further comprising:
a first light-shielding layer located at a side of the support layer away from the pixel definition layer, wherein the first light-shielding layer comprises a plurality of first light-shielding portions arranged at intervals, the plurality of first light-shielding portions at least partially cover the support portions, and at least one of the first light-shielding portions comprises a first predetermined light-shielding portion;
wherein, along the first direction, the first opening area and the second opening area are located at two sides of the first predetermined light-shielding portion and are adjacent to the first predetermined light-shielding portion, and along the first direction, a minimum distance between the first predetermined light-shielding portion and the first opening area is L1, and a minimum distance between the first predetermined light-shielding portion and the second opening area is L2, wherein L1≠L2, and wherein in an orthographic projection plan view, the first light-shielding portions at least partially overlap with the pixel definition portions.

6. The display panel according to claim 5, wherein L1=D1 and/or L2=D2.

7. The display panel according to claim 5, wherein L1≠D1 and/or L2≠D2.

8. The display panel according to claim 5, wherein at least one of the first light-shielding portions further comprises a second predetermined light-shielding portion, and along the first direction, the first opening area is located between the first predetermined light-shielding portion and the second predetermined light-shielding portion, and a distance between the second predetermined light-shielding portion and the first opening area is L3, wherein L1≠L3.

9. The display panel according to claim 5, wherein in an orthographic projection plan view, the first light-shielding portions cover orthographic projections of the support portions.

10. The display panel according to claim 5, further comprising:
an encapsulation layer located between the first light-shielding layer and the support layer.

11. The display panel according to claim 1, further comprising:
a first organic layer located at a side of the support layer away from the display substrate; and
a second organic layer located at a side of the first organic layer away from the light-emitting layer, wherein a refractive index of the second organic layer is greater than a refractive index of the first organic layer.

12. The display panel according to claim 11, wherein two ends of the second organic layer have different minimum distances from a center of the sub-pixels.

13. The display panel according to claim 11, wherein the first organic layer comprises a plurality of first organic layer openings arranged at intervals, and orthographic projections of the first organic layer openings on the display substrate overlap with orthographic projection of the opening area on the display substrate.

14. The display panel according to claim 13, wherein a surface of the first organic layer openings facing the display substrate is a concave surface, and a surface of the second organic layer close to the display substrate is a convex surface.

15. The display panel according to claim 11, further comprising:
a third organic layer located at a portion of a surface of the second organic layer away from the first organic layer, wherein a refractive index of the third organic layer is greater than the refractive index of the second organic layer.

16. The display panel according to claim 15, wherein an orthographic projection of the third organic layer on the display substrate at least partially overlaps with orthographic projections of the sub-pixels on the display substrate.

17. The display panel according to claim 15, wherein the third organic layer comprises a first organic portion and a second organic portion, an orthographic projection of the first organic portion on the display substrate at least partially overlaps with orthographic projections of the sub-pixels on the display substrate, an orthographic projection of the second organic portion on the display substrate at least partially overlaps with the orthographic projections of the sub-pixels on the display substrate, the orthographic projection of the first organic portion on the display substrate does not overlap with the orthographic projection of the second organic portion on the display substrate, and a refractive index of the first organic portion is less than a refractive index of the second organic portion.

18. The display panel according to claim 17, wherein a surface of the first organic portion away from the second organic layer is a convex surface, and a surface of the second organic portion away from the second organic layer is a convex surface.

19. The display panel according to claim 15, further comprising:
a fourth organic layer located at a side of the third organic layer away from the second organic layer.

20. The display panel according to claim 19, further comprising:
a second light-shielding layer located between the fourth organic layer and the first organic layer, wherein the second light-shielding layer comprises a plurality of second light-shielding portions arranged at intervals, one of the second light-shielding portions is correspondingly provided at a surface of one of the support portions away from the display substrate, at least part of the second light-shielding portions have different minimum distances from two adjacent opening areas, and wherein orthographic projections of the second light-shielding portions on the display substrate at least partially overlaps with orthographic projections of the pixel definition portions on the display substrate.

21. A display apparatus, comprising a display panel, wherein the display panel comprises:
a display substrate;
a pixel definition layer located on a side of the display substrate, wherein the pixel definition layer comprises a plurality of pixel definition portions, and an opening area is provided between two adjacent pixel definition portions;
a plurality of sub-pixels, wherein at least one of the plurality of sub-pixels comprises a light-emitting layer, and the light-emitting layer is at least partially located in the opening area; and
a support layer located at a side of the light-emitting layer away from the display substrate, wherein the support layer comprises a plurality of support portions, and the plurality of support portions are located on a side of the plurality of pixel definition portions away from the display substrate, and comprise a first support portion;
wherein, along a first direction, the opening area comprises a first opening area adjacent to the first support portion and a second opening area adjacent to the first support portion, and along the first direction, a minimum distance between the first support portion and the first opening area is D1, and a minimum distance between the first support portion and the second opening area is D2, wherein D1≠D2, and wherein the first direction is perpendicular to a thickness direction of the display substrate.
